(19) United States
(12) Patent Application Publication
(10) Pub. No.: US 2025/0365943 A1
(43) Pub. Date: Nov. 27, 2025

(54) SEMICONDUCTOR MEMORY DEVICE

(71) Applicant: Samsung Electronics Co., Ltd., Suwon-si (KR)

(72) Inventor: Jong In Kang, Suwon-si (KR)

(21) Appl. No.: 19/021,970

(22) Filed: Jan. 15, 2025

(30) Foreign Application Priority Data
May 22, 2024 (KR) 10-2024-0066570

(51) Int. Cl. H10B 12/00

(52) U.S. Cl. CPC H10B 12/488; H10B 12/315; H10B 12/34; H10B 12/50

(57) ABSTRACT

A semiconductor memory device includes a substrate including a cell region, and a peri-region defined around the cell region, a cell region isolation film that is disposed in the substrate and isolates the cell region and the peri-region, a first cell gate structure disposed in the cell region and the cell region isolation film, and including a first cell gate electrode extending in a first direction, and a first cell gate plug disposed on the first cell gate electrode and connected to the first cell gate electrode.

### CROSS-REFERENCE TO RELATED APPLICATION(S)

This application claims priority to Korean Patent Application No. 10-2024-0066570, filed in the Korean Intellectual Property Office on May 22, 2024, the contents of which are herein incorporated by reference in its entirety.

### BACKGROUND

As a semiconductor element becomes more highly integrated, individual circuit patterns are further reduced to implement more semiconductor elements in the same area. That is, as an integration degree of the semiconductor elements increases, the constituent elements of the semiconductor elements are generally decreasing.

In highly scaled semiconductor elements, a process of forming a plurality of wiring lines and a plurality of buried contacts (BC) interposed between them becomes increasingly complex and difficult.

### SUMMARY

In general, in some aspects, the present disclosure is directed toward a semiconductor memory device having improved reliability and performance.

According to some implementations, the present disclosure is directed to a semiconductor memory device comprising a substrate including a cell region and a peri-region defined around the cell region, a cell region isolation film disposed in the substrate and isolates the cell region and the peri-region, a first cell gate structure disposed in the cell region and the cell region isolation film, and including a first cell gate electrode extending in a first direction, and a first cell gate plug disposed on the first cell gate electrode and connected to the first cell gate electrode, wherein the first cell gate electrode includes a first long side wall and a second long side wall which extend in the first direction and opposing to each other in a second direction, wherein, from viewpoint of a plan view, a length of the first cell gate plug contacting the first long side wall of the first cell gate electrode is a first contact length, wherein a length of the first cell gate plug contacting the second long side wall of the first cell gate electrode is a second contact length, wherein the first contact length is greater than the second contact length.

According to some implementations, the present disclosure is directed to a semiconductor memory device comprising a substrate including a cell region and a peri-region defined around the cell region, a cell region isolation film disposed in the substrate and isolates the cell region and the peri-region, a first cell gate structure disposed in the cell region and the cell region isolation film, and including a first cell gate electrode extending in a first direction, and a first cell gate plug disposed on the first cell gate electrode and connected to the first cell gate electrode, wherein the first cell gate electrode includes a body region and a contact region, wherein the contact region of the first cell gate electrode is connected to the first cell gate plug and disposed in the cell region isolation film, wherein the first cell gate electrode includes a first long side wall and a second long side wall extending in the first direction and opposing each other in a second direction, wherein the body region of the first cell gate electrode includes a first width center line extending in the first direction, wherein the first cell gate plug includes a first plug width center line extending in the first direction, wherein the first width center line is spaced apart from the first plug width center line in the second direction.

According to some implementations, the present disclosure is directed to a semiconductor memory device comprising a substrate including a cell region and a peri-region defined around the cell region, a cell region isolation film disposed in the substrate and isolates the cell region and the peri-region, a cell gate structure disposed in the cell region and the cell region isolation film, and includes a cell gate electrode extending in a first direction, and a cell gate plug disposed on the cell gate electrode and connected to the cell gate electrode, wherein the first cell gate electrode includes a body region and a contact region, wherein the contact region of the cell gate electrode is connected to the cell gate plug and disposed in the cell region isolation film, wherein the contact region of the cell gate electrode includes a first connecting portion extending in a second direction different from the first direction, and a first extending portion extending in the first direction, wherein the first connecting portion connects the first extending portion to the body region of the cell gate electrode, wherein the first extending portion does not overlap the body region of the cell gate electrode in a third direction perpendicular to the first direction.

### BRIEF DESCRIPTION OF DRAWINGS

Example implementations will be more clearly understood from the following detailed description, taken in conjunction with the accompanying drawings.

FIG. 1 is a schematic layout diagram of an example of a semiconductor memory device according to some implementations.

FIG. 2 is a layout of an example of a region R1 of FIG. 1 according to some implementations.

FIG. 3 is a layout showing examples of a word line and a cell active region of FIG. 2 according to some implementations.

FIG. 4 is a plan view showing an example of a region R2 of FIG. 1 according to some implementations.

FIGS. 5 to 8 are cross-sectional views taken along A-A, B-B, C-C, and D-D of FIG. 4 according to some implementations.

FIG. 9 is a diagram showing an example of a placement relationship between a cell gate electrode and a cell gate plug included in the cell gate structure of FIG. 4 according to some implementations.

FIG. 10 is a diagram showing an example in which the cell gate plug lands on the cell gate electrode in FIG. 9 according to some implementations.

FIG. 11 is a diagram showing an example of a position of a width center line of the cell gate plug according to some implementations.

FIGS. 12 and 13 are diagrams showing an example of a semiconductor memory device according to some implementations.

FIG. 14 is a diagram showing an example of a semiconductor memory device according to some implementations.

FIGS. 15 and 16 are diagrams showing an example of a semiconductor memory device according to some implementations.

FIG. 17 is a diagram showing an example of a semiconductor memory device according to some implementations.

FIG. 18 is a diagram showing an example of a semiconductor memory device according to some implementations.

FIGS. 19 and 20 are cross-sectional views taken along lines A-A and B-B of FIG. 18 according to some implementations.

FIG. 21 is a diagram showing an example of a placement relationship between the cell gate electrode and the cell gate plug included in the cell gate structure of FIG. 18 according to some implementations.

FIGS. 22 and 23 are diagrams showing an example of a semiconductor memory device according to some implementations.

### DETAILED DESCRIPTION

Hereinafter, example implementations will be explained in detail with reference to the accompanying drawings.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Accordingly, a first element, component, region, layer or section described below could be termed a second element, component, region, layer or section, without departing from the spirit and scope of the present disclosure.

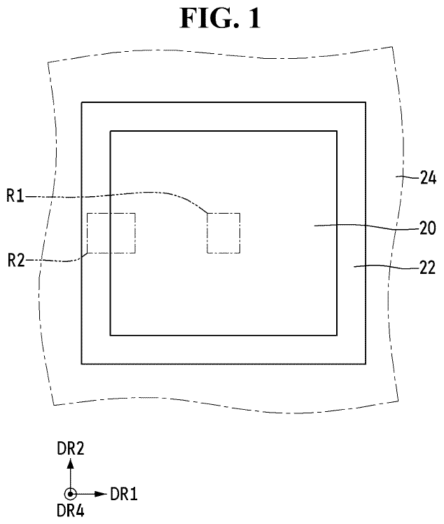

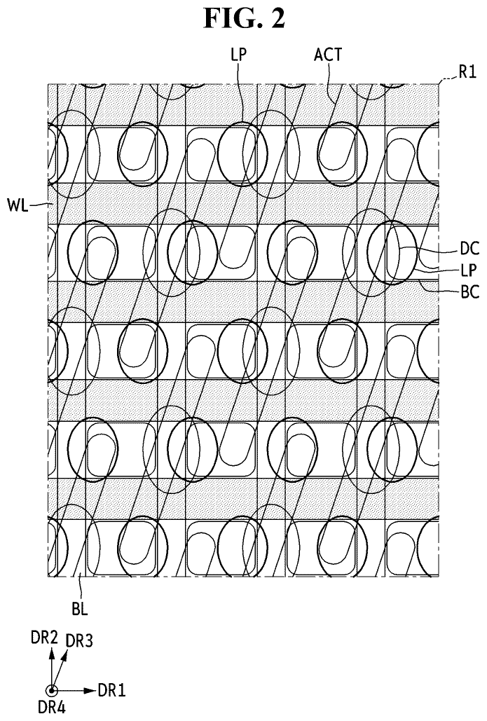

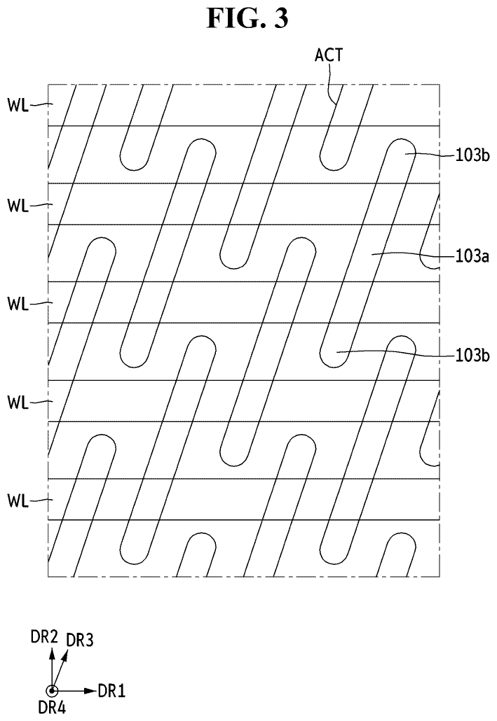

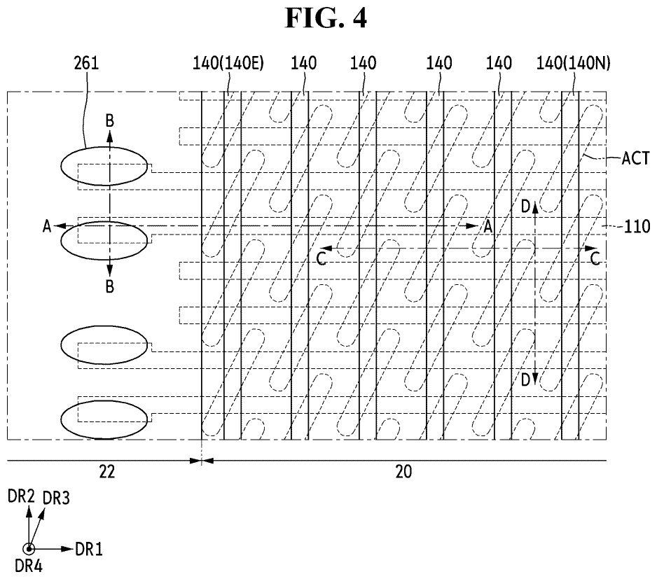

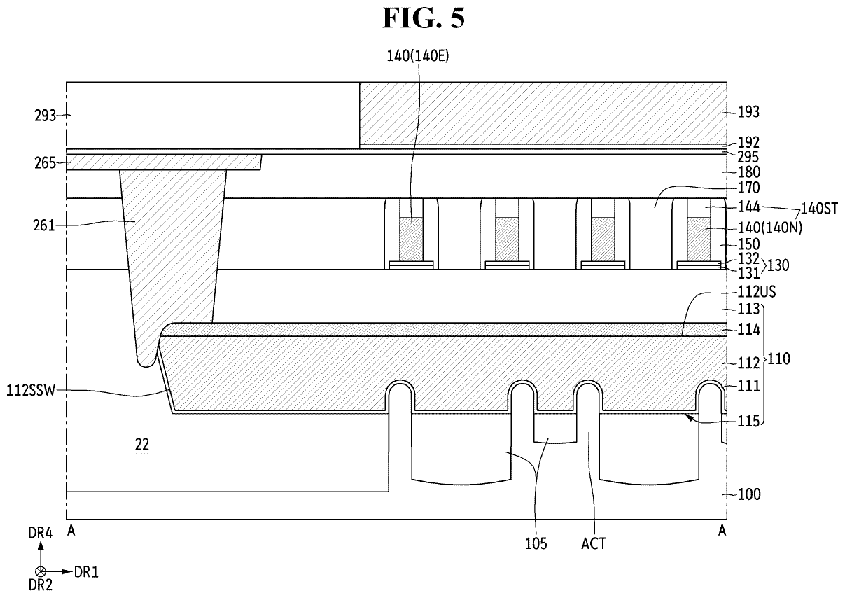

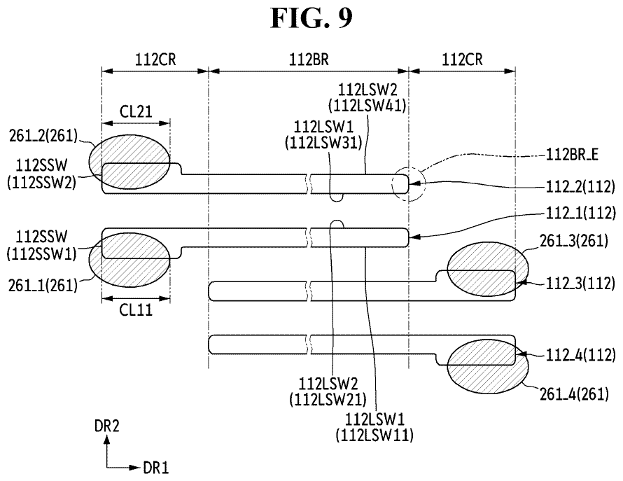

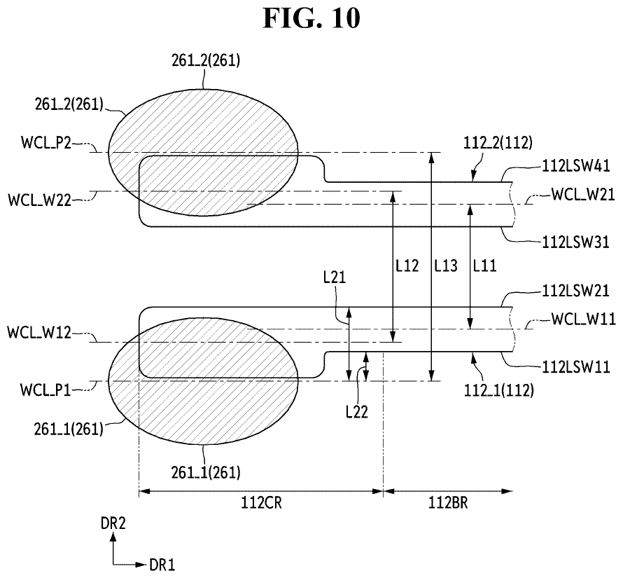

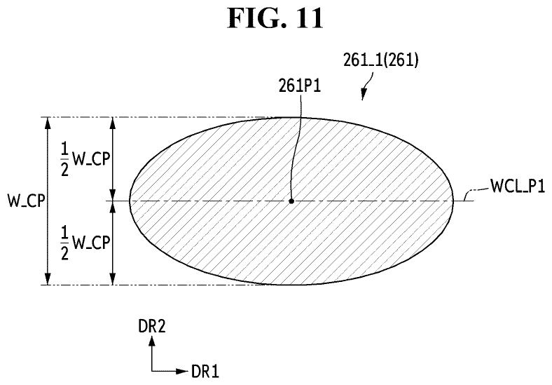

FIG. 1 is a schematic layout diagram of an example of a semiconductor memory device according to some implementations. FIG. 2 is a layout of an example of a region R1 of FIG. 1 according to some implementations. FIG. 3 is a layout showing examples of a word line and a cell active region of FIG. 2 according to some implementations. FIG. 4 is a plan view showing an example of a region R2 of FIG. 1 according to some implementations. FIGS. 5 to 8 are cross-sectional views taken along A-A, B-B, C-C, and D-D of FIG. 4 according to some implementations. FIG. 9 is a diagram showing an example of a placement relationship between a cell gate electrode and a cell gate plug included in the cell gate structure of FIG. 4 according to some implementations. FIG. 10 is a diagram showing an example in which the cell gate plug lands on the cell gate electrode in FIG. 9 according to some implementations. FIG. 11 is a diagram showing an example of a position of a width center line of the cell gate plug according to some implementations. For reference, FIG. 4 shows only a cell active region ACT, a cell gate structure 110, a cell conductive line 140, and a cell gate plug 261.

In some implementations, a dynamic random access memory (DRAM) is shown as an example, but the present disclosure is not limited thereto.

In FIGS. 1 to 4 and 9, a semiconductor memory device may include a cell region 20, a cell region isolation film 22, and a peri-region 24. The cell region isolation film 22 may be formed along the periphery of the cell region 20. The cell region isolation film 22 may isolate the cell region 20 and the peri-region 24. The cell region 20 may be defined by the cell region isolation film 22. The peri-region 24 may be defined around the cell region 20.

The cell region 20 may include a plurality of cell active regions ACT. The cell active regions ACT may be defined by cell element isolation films (105 of FIGS. 5, 7, and 8) formed in a substrate (100 of FIGS. 5 to 8). As the design rule of the semiconductor memory devices decreases, the cell active regions ACT may be disposed in the form of bar of a diagonal line or an oblique line, as shown. For example, the cell active region ACT may extend in a third direction DR3.

A plurality of gate electrodes extending in a first direction DR1 across the cell active regions ACT may be disposed. The plurality of gate electrodes may extend to be parallel to each other. The plurality of gate electrodes may be, for example, a plurality of word lines WL. The word lines WL may be disposed at equal intervals. A width of the word lines WL or an interval between the word lines WL may be determined depending on a design rule. The conductive lines included in the cell gate structure 110 may be word lines WL.

For example, the word lines WL may extend up to the cell region isolation film 22. A part of the word lines WL may overlap the cell region isolation film 22 in a fourth direction DR4.

Each cell active region ACT may be divided into three portions by two word lines WL extending in the first direction DR1. The cell active region ACT may include a bit line connecting region 103a and a storage connecting region 103b. The bit line connecting region 103a may be located at the center of the cell active region ACT, and the storage connecting region 103b may be located at an end of the cell active region ACT.

A plurality of bit lines BL extending in a second direction DR2 perpendicular to the word lines WL may be disposed on the word line WL. The plurality of bit lines BL may extend to be parallel to each other. The bit lines BL may be disposed at equal intervals. The width of the bit lines BL or the interval between the bit lines BL may be determined depending on design rules.

The bit line BL may extend up to the cell region isolation film 22. A part of the bit line BL may overlap the cell region isolation film 22 in the fourth direction DR4. The fourth direction DR4 may be perpendicular to the first direction DR1, the second direction DR2, and the third direction DR3. The fourth direction DR4 may be a thickness direction of the substrate 100. The first direction DR1 may be perpendicular to the second direction DR2. The third direction DR3 may form any angle with respect to the first direction DR1 and the second direction DR2.

The bit line BL may include a cell conductive line 140. The cell conductive line 140 may include a normal cell conductive line 140N and an edge cell conductive line 140E. For example, the edge cell conductive line 140E may be a cell conductive line disposed at an outermost corner of the cell conductive lines 140.

Although a width of the edge cell conductive line 140E in the first direction DR1 is shown as being the same as a width of the normal cell conductive line 140N in the first direction DR1, the present disclosure is not limited thereto. Unlike the shown example, the width of the edge cell conductive line 140E in the first direction DR1 may be greater than the width of the normal cell conductive line 140N in the first direction DR1.

In some implementations, the semiconductor memory device may include various contact arrangements formed on the cell active region ACT. The various contact arrangements may include, for example, a direct contact DC, a buried contact BC, a landing pad LP, and the like.

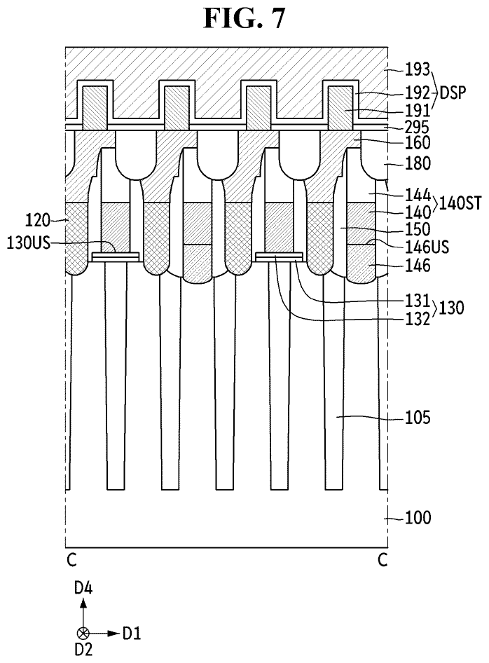

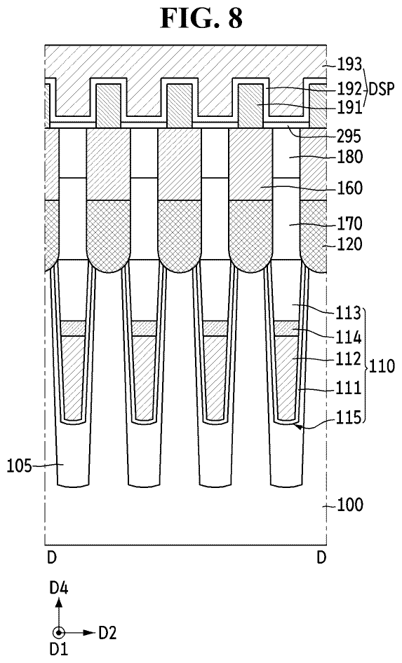

Here, the direct contact DC may refer to a contact that electrically connects the cell active region ACT to the bit line BL. The buried contact BC may refer to a contact that connects the cell active region ACT to the lower electrode (191 of FIGS. 7 and 8) of the data storage pattern. Due to the layout structure, the contact area between the buried contact BC and the cell active region ACT may be small. Accordingly, a conductive landing pad LP may be introduced to enlarge a contact area with the cell active region ACT and a contact area with the lower electrode (191 of FIGS. 7 and 8).

The landing pad LP may be disposed between the cell active region ACT and the buried contact BC, or may be disposed between the buried contact BC and the lower electrode (191 of FIGS. 7 and 8). In some implementations, the landing pad LP may be disposed between the buried contact BC and the lower electrode of a data storage pattern DSP. By enlarging the contact area through the introduction of the landing pad LP, the contact resistance between the cell active region ACT and the capacitor lower electrode may be reduced.

The direct contact DC may be connected to the bit line connecting region 103a. The buried contact BC may be connected to the storage connecting region 103b. As the buried contact BC is disposed at both ends of the cell active region ACT, the landing pad LP may be disposed adjacent to both ends of the cell active region ACT to partially overlap the buried contact BC. In other words, the buried contact BC may be formed to overlap the cell active region ACT and the cell element isolation film (105 of FIG. 8) between the adjacent word lines WL and between the adjacent bit lines BL.

The word line WL may be formed as a buried structure inside the substrate 100. The word line WL may be disposed across the cell active region ACT between the direct contact DC and the buried contact BC. As shown, two word lines WL may be disposed to cross one cell active region ACT. Because the cell active region ACT extends along the third direction DR3, the word line WL may have an angle of less than 90 degrees with the cell active region ACT.

The direct contact DC and the buried contact BC may be disposed symmetrically. Accordingly, the direct contact DC and the buried contact BC may be disposed in a straight line along the first direction DR1 and the second direction DR2.

On the other hand, unlike the direct contact DC and the buried contact BC, the landing pad LP may be disposed in zigzags in the second direction DR2 in which the bit lines BL extend. Also, the landing pad LP may be disposed to overlap the same side face portion of the bit line BL in the first direction DR1 in which the word lines WL extend.

For example, each of the landing pads LP of the first line may overlap a left side face of the corresponding bit line BL, and each of the landing pads LP of the second line may overlap a right side face of the corresponding bit line BL.

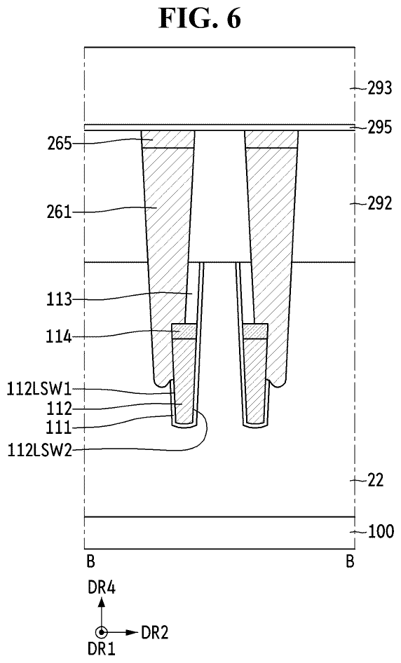

A plurality of cell gate plugs 261 may be disposed on the cell gate structure 110. The plurality of cell gate plugs 261 may be connected to the cell gate structure 110. For example, the plurality of cell gate plugs 261 may be connected to the cell gate electrode (112 of FIGS. 5 and 6) included in the cell gate structure 110.

The cell gate plug 261 may be connected to the cell gate electrode 112 in the vicinity of the end of the cell gate structure 110, that is, in the vicinity of the end of the word line WL. A placement relationship between the cell gate plug 261 and the cell gate electrode 112 will be explained below.

In FIGS. 1 to 11, the semiconductor memory device may include a cell active region ACT, a plurality of cell gate structures 110, a plurality of cell conductive lines 140, a plurality of storage pads 160, a data storage pattern DSP, and a plurality of cell gate plugs 261.

The substrate 100 may include a cell region 20, a cell region isolation film 22, and a peri-region 24. The substrate 100 may be a silicon substrate or a silicon-on-insulator (SOI). In contrast, the substrate 100 may include, but not limited to, silicon germanium, silicon germanium on insulator (SGOI), indium antimonide, lead telluride, indium arsenide, indium phosphide, gallium arsenide or gallium antimonide.

A plurality of cell gate structures 110, a plurality of bit line structures 140ST, a plurality of storage pads 160, and a data storage pattern DSP may be disposed in the cell region 20.

A cell element isolation film 105 may be formed inside the substrate 100 of the cell region 20. The cell element isolation film 105 may have a shallow trench isolation (STI) structure having excellent element isolation characteristics. The cell region isolation film 22 may have the STI structure, like the cell element isolation film 105.

The cell element isolation film 105 may define a cell active region ACT inside the cell region 20. The cell active region ACT defined by the cell element isolation film 105 may have a long island formation including a short axis and a long axis as shown in FIGS. 2 to 4.

The cell active region ACT may have an oblique line shape to have an angle of less than 90 degrees with respect to the word line WL disposed in the cell element isolation film 105. The cell active region ACT may have an oblique line shape to have an angle of less than 90 degrees with respect to the bit line BL formed on the cell element isolation film 105.

In other words, the cell active region ACT may have an oblique line shape to have an angle of less than 90 degrees with respect to the cell gate structure 110 disposed in the cell element isolation film 105. The cell active region ACT may have an oblique line shape to have an angle of less than 90 degrees with respect to the bit line structure 140ST formed on the cell element isolation film 105.

A depth from an upper surface of the cell region isolation film 22 to the lowermost part of the cell region isolation film 22 may be the same as a depth from the upper surface of the cell region isolation film 22 to the lowermost part of the cell element isolation film 105, but the present disclosure is not limited thereto. Unlike the shown example, the depth from the upper surface of the cell region isolation film 22 to the lowermost part of the cell region isolation film 22 may be different from the depth from the upper surface of the cell region isolation film 22 to the lowermost part of the cell element isolation film 105.

The cell element isolation film 105 and the cell region isolation film 22 may each include, for example, but not limited to, at least one of a silicon oxide film, a silicon nitride film, and a silicon oxynitride film. In FIGS. 5 to 8, although the cell element isolation film 105 and the cell region isolation film 22 are each shown as being formed of one insulating film, this is only for convenience of explanation, and the present disclosure is not limited thereto. Depending on the width of the cell element isolation film 105 and the cell region isolation film 22, the cell element isolation film 105 and the cell region isolation film 22 may each be formed of one insulating film or may be formed of a plurality of insulating films.

In FIG. 7, although the upper surface of the cell element isolation film 105 and the upper surface of the substrate 100 are shown as being placed on the same plane, is only for convenience of explanation, and the present disclosure is not limited thereto.

A plurality of cell gate structures 110 may be disposed inside the cell region 20 and the cell region isolation film 22. Each cell gate structure 110 may be formed inside the substrate 100 and the cell element isolation film 105. The cell gate structure 110 may be formed across the cell element isolation film 105 and the cell active region ACT defined by the cell element isolation film 105. A part of the cell gate structure 110 may be disposed inside the cell region isolation film 22.

The cell gate structure 110 may include a cell gate trench 115 disposed inside the substrate 100 and the cell element isolation film 105, a cell gate insulating film 111, a cell gate electrode 112, a cell gate capping pattern 113 and a cell gate capping conductive film 114. Here, the cell gate electrode 112 may correspond to the word line WL. Unlike the shown example, the cell gate structure 110 may not include the cell gate capping conductive film 114.

The cell gate trench 115 may be relatively deep in the cell element isolation film 105, and relatively shallow in the cell active region ACT. The bottom face of the cell gate electrode 112 may be curved. That is, the depth of the cell gate trench 115 in the cell element isolation film 105 may be greater than the depth of the cell gate trench 115 in the cell active region ACT.

The cell gate insulating film 111 may extend along side walls and a bottom face of the gate trench 115. The cell gate insulating film 111 may extend along a profile of at least a part of the cell gate trench 115. The cell gate insulating film 111 may include, for example, at least one of silicon oxide, silicon nitride, silicon oxynitride or a high dielectric constant material having a higher dielectric constant than that of silicon oxide. The high dielectric constant material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations thereof.

The cell gate electrode 112 may be disposed on the cell gate insulating film 111. The cell gate electrode 112 may fill a part of the cell gate trench 115.

The cell gate capping conductive film 114 may extend along the upper surface 112US of the cell gate electrode. In some implementations, the cell gate capping conductive film 114 may cover the entire upper surface 112US of the cell gate electrode.

The cell gate electrode 112 may include a conductive material, and may include, for example, at least one of doped polysilicon, conductive metal nitride, conductive metal silicon nitride, metal carbonitride, conductive metal silicide, conductive metal oxide, two-dimensional material, metal, and metal alloy. The cell gate capping conductive film 114 may include, for example, but not limited to, polysilicon or polysilicon-germanium.

Each cell gate electrode 112 may include a first long side wall 112LSW1 and a second long side wall 112LSW2 that extend in the first direction DR1. The first long side wall 112LSW1 of the cell gate electrode is opposite to the second long side wall 112LSW2 of the cell gate electrode in the second direction DR2.

From viewpoint of a plan view, one of the long side walls 112LSW1 and 112LSW2 of the cell gate electrode may have a straight line shape. The other of the long side walls 112LSW1 and 112LSW2 of the cell gate electrode may have a stepped shape formed by expansion of the end portion of the cell gate electrode 112.

Here, the long side walls 112LSW1 and 112LSW2 of the cell gate electrode having a straight line shape are shown as straight lines without roughness only for convenience of explanation. Unlike the shown example, the long side walls 112LSW1 and 112LSW2 of the cell gate electrode having a straight line shape may include a roughness. The long side walls 112LSW1 and 112LSW2 of the cell gate electrode have a straight line shape, which means that the inclined shape may have the form of a straight line extending in the first direction DR1.

The long side walls 112LSW1 and 112LSW2 of the cell gate electrode having the stepped shape may include a first straight line portion and a second straight line portion extending in the first direction, and a connecting portion that connects the first straight line portion and the second straight line portion.

Each cell gate electrode 112 may include a short side wall 112SSW that connects the first long side wall 112LSW1 of the cell gate electrode and the second long side wall 112LSW2 of the cell gate electrode. The short side wall 112SSW of the cell gate electrode may extend in the second direction DR2. In plan view, although the short side wall 112SSW of the cell gate electrode is shown to include a straight line portion extending in the second direction DR2, this is only for convenience of explanation, and the present disclosure is not limited thereto. Unlike the shown example, the short side wall 112SSW of the cell gate electrode may have a convex curved face shape.

Each cell gate electrode 112 may include a body region 112BR and a contact region 112CR. The contact region 112CR of the cell gate electrode may be a portion connected to a cell gate plug 261 to be explained below. In other words, the contact region 112CR of the cell gate electrode may be a region on which the cell gate plug 261 lands.

The contact region 112CR of the cell gate electrode may be disposed inside the cell region isolation film 22. The contact region 112CR of the cell gate electrode may overlap the cell region isolation film 22 in the fourth direction DR4. The contact region 112CR of the cell gate electrode may include long side walls 112LSW1 and 112LSW2 of the cell gate electrode having a stepped shape formed by expansion of the end portion of the cell gate electrode 112.

The body region 112BR of the cell gate electrode may be disposed in the cell region 20. A part of the body region 112BR of the cell gate electrode may be disposed inside the cell region isolation film 22.

The cell gate electrode 112 may include a trailing end 112BR_E. For example, the body region 112BR of the cell gate electrode includes a trailing end 112BR_E of the cell gate electrode 112. The trailing end 112BR_E of the cell gate electrode 112 may be located in a portion opposite to the contact region 112CR of the cell gate electrode in the first direction DR1. In some implementations, the width of the cell gate electrode 112 in the second direction DR2 at the trailing end 112BR_E of the cell gate electrode 112 may decrease as it goes away from the contact region 112CR of the cell gate electrode.

In FIGS. 9 and 10, the cell gate electrode 112 may include first to fourth cell gate electrodes 112_1, 112_2, 112_3, and 112_4. A first cell gate electrode 112_1 and a second cell gate electrode 112_2 may be closest to each other in the second direction DR2. An additional cell gate electrode is not disposed between the first cell gate electrode 112_1 and the second cell gate electrode 112_2. A third cell gate electrode 112_3 and a fourth cell gate electrode 112_4 may be closest to each other in the second direction DR2. An additional cell gate electrode is not disposed between the third cell gate electrode 112_3 and the fourth cell gate electrode 112_4.

The first cell gate electrode 112_1 may be disposed between the second cell gate electrode 112_2 and the third cell gate electrode 112_3. The first cell gate electrode 112_1 and the third cell gate electrode 112_3 may be closest to each other in the second direction DR2. An additional cell gate electrode is not disposed between the first cell gate electrode 112_1 and the third cell gate electrode 112_3.

The body region 112BR of the first cell gate electrode 112_1 may overlap the body region 112BR of the third cell gate electrode 112_3 in the second direction DR2. The contact region 112CR of the first cell gate electrode 112_1 does not overlap the body region 112BR of the third cell gate electrode 112_3 in the second direction DR2. The contact region 112CR of the third cell gate electrode 112_3 does not overlap the body region 112BR of the first cell gate electrode 112_1 in the second direction DR2.

The contact region 112CR of the second cell gate electrode 112_2 does not overlap the body region 112BR of the third cell gate electrode 112_3 in the second direction DR2. The contact region 112CR of the fourth cell gate electrode 112_4 does not overlap the body region 112BR of the first cell gate electrode 112_1 in the second direction DR2.

The contact region 112CR of the first cell gate electrode 112_1 may overlap the contact region 112CR of the second cell gate electrode 112_2 in the second direction DR2. The contact region 112CR of the third cell gate electrode 112_3 may overlap the contact region 112CR of the fourth cell gate electrode 112_4 in the second direction DR2.

The contact region 112CR of the first cell gate electrode 112_1 and the contact region 112CR of the second cell gate electrode 112_2 may be a portion that protrudes from the trailing end 112BR_E of the third cell gate electrode 112_3 in the first direction DR1. The contact region 112CR of the third cell gate electrode 112_3 and the contact region 112CR of the fourth cell gate electrode 112_4 may be portions that protrude from the trailing end 112BR_E of the first cell gate electrode 112_1 in the first direction DR1.

The first cell gate electrode 112_1 may include a first sub-long side wall 112LSW11 and a second sub-long side wall 112LSW21 that are opposite to each other in the second direction DR2. The first sub-long side wall 112LSW11 of the first cell gate electrode 112_1 may be the first long side wall 112LSW1 of the first cell gate electrode 112_1. The second sub-long side wall 112LSW21 of the first cell gate electrode 112_1 may be the second long side wall 112LSW2 of the first cell gate electrode 112_1.

The second cell gate electrode 112_2 may include a third sub-long side wall 112LSW31 and a fourth sub-long side wall 112LSW41 that are opposite to each other in the second direction DR2. The third sub-long side wall 112LSW31 of the second cell gate electrode 112_2 may be the first long side wall 112LSW1 of the second cell gate electrode 112_2. The fourth sub-long side wall 112LSW41 of the second cell gate electrode 112_2 may be the second long side wall 112LSW2 of the second cell gate electrode 112_2.

The second long side wall 112LSW2 of the first cell gate electrode may face the first long side wall 112LSW1 of the second cell gate electrode 112_2. The second long side wall 112LSW2 of the first cell gate electrode 112_1 may face the second cell gate electrode 112_2. The first long side wall 112LSW1 of the second cell gate electrode 112_2 may face the first cell gate electrode 112_1.

The first cell gate electrode 112_1 may include a first sub-short side wall 112SSW1 that connects the first sub-long side wall 112LSW11 and the second sub-long side wall 112LSW21. The second cell gate electrode 112_2 may include a second sub-short side wall 112SSW2 that connects the third sub-long side wall 112LSW31 and the fourth sub-long side wall 112LSW41.

The second sub-long side wall 112LSW21 of the first cell gate electrode 112_1 may face the third sub-long side wall 112LSW31 of the second cell gate electrode 112_2. The first sub-long side wall 112LSW11 of the first cell gate electrode 112_1 and the fourth sub-long side wall 112LSW41 of the second cell gate electrode 112_2 may include a stepped shape formed by expansion of the end portion of the cell gate electrode 112.

From viewpoint of a plan view, the body region 112BR of the first cell gate electrode 112_1 may include a first body width center line WCL_W11. The first body width center line WCL_W11 may extend in the first direction DR1. The first body width center line WCL_W11 may pass through the center of the width of the body region 112BR of the first cell gate electrode 112_1 in the second direction DR2.

For example, in the body region 112BR of the first cell gate electrode 112_1, the first sub-long side wall 112LSW11 and the second sub-long side wall 112LSW21 may be aligned in the first direction DR1. In this case, the first sub-long side wall 112LSW11 and the second sub-long side wall 112LSW21 may be spaced apart by a first electrode width. The first body width center line WCL_W11 may pass through a point that is half the first electrode width and extend in the first direction DR1.

In a plan view, the contact region 112CR of the first cell gate electrode 112_1 may include a first contact width center line WCL_W12. The first contact width center line WCL_W12 may extend in the first direction DR1. The first contact width center line WCL_W12 may pass through the center of the width of the contact region 112CR of the first cell gate electrode 112_1 in the second direction DR2.

For example, in the contact region 112CR of the first cell gate electrode 112_1, the first sub-long side wall 112LSW11 and the second sub-long side wall 112LSW21 may be spaced apart by a second electrode width. In the contact region 112CR of the first cell gate electrode 112_1, the width of the first cell gate electrode 112_1 in the second direction DR2 may change. For example, the second electrode width may be the largest value among the widths of the first cell gate electrode 112_1 in the contact region 112CR of the first cell gate electrode 112_1. The first contact width center line WCL_W12 may pass through a point that is half the second electrode width, and extend in the first direction DR1.

The explanation of the width center line may be supplemented through the explanation of a plug width center line to be explained below with respect to FIG. 11.

In a plan view, the body region 112BR of the second cell gate electrode 112_2 may include a second body width center line WCL_W21. The contact region 112CR of the second cell gate electrode 112_2 may include a second contact width center line WCL_W22.

The first contact width center line WCL_W12 may be spaced apart from the first body width center line WCL_W11 in the second direction DR2. For example, the first contact width center line WCL_W12 may be parallel to the first body width center line WCL_W11. The first contact width center line WCL_W12 may not meet the first body width center line WCL_W11.

The first body width center line WCL_W11 and the second body width center line WCL_W21 may be parallel to each other. The first body width center line WCL_W11 and the second body width center line WCL_W21 may be spaced apart by a first spaced distance L11 in the second direction DR2.

The first contact width center line WCL_W12 and the second contact width center line WCL_W22 may be parallel to each other. The first contact width center line WCL_W12 and the second contact width center line WCL_W22 may be spaced apart by a second spaced distance L12 in the second direction DR2. For example, the second spaced distance L12 is greater than the first spaced distance L11.

The explanation of the first cell gate electrode 112_1 and the second cell gate electrode 112_2 may be applied to the third cell gate electrode 112_3 and the fourth cell gate electrode 112_4.

The cell gate capping pattern 113 may be disposed on the cell gate electrode 112 and the cell gate capping conductive film 114. The cell gate capping pattern 113 may fill the cell gate trench 115 that remains after the cell gate electrode 112 and the cell gate capping conductive film 114 are formed. Although the cell gate insulating film 111 is shown to extend along the side wall of the cell gate capping pattern 113, the present disclosure is not limited thereto.

The cell gate capping pattern 113 includes an upper surface of the cell gate structure 110. The upper surface of the cell gate capping pattern 113 may be the upper surface of the cell gate structure 110. The cell gate capping pattern 113 may include, for example, at least one of silicon nitride (SiN), silicon oxynitride (SiON), silicon oxide (SiO₂), silicon carbonitrde (SiCN), silicon oxcarbonitride (SiOCN), and combinations thereof.

An impurity doping region may be formed on at least one side of the cell gate structure 110. The impurity doping region may be a source/drain region of a transistor. The impurity doping region may be formed in the storage connecting region 103b and the bit line connecting region 103a of FIG. 3.

The bit line structure 140ST may include a cell conductive line 140 and a cell line capping film 144. The bit line structure 140ST may include a normal cell conductive line 140N and a cell line capping film 144. The bit line structure 140ST disposed at the outermost corner of the cell region 20 may include an edge cell conductive line 140E. The cell conductive line 140 may be disposed on the substrate 100 and the cell element isolation film 105 in which the cell gate structure 110 is disposed.

The cell conductive line 140 may extend in the second direction DR2. The cell conductive line 140 may cross the cell element isolation film 105 and the cell active region ACT defined by the cell element isolation film 105. Here, the cell conductive line 140 may correspond to the bit line BL.

The cell conductive line 140 may include at least one of, for example, a semiconductor material doped with impurities, a conductive silicide compound, a conductive metal nitride, a two-dimensional (2D) material, a metal, and a metal alloy. In some implementations, the 2D material may be a metallic material and/or a semiconductor material. The 2D material may include a 2D allotrope or a 2D compound, and may include, but not limited to, at least one of graphene, molybdenum disulfide (MoS₂), molybdenum diselenide (MoSe₂), tungsten diselenide (WSe₂), and tungsten disulfide (WS₂). That is, since the above-mentioned 2D materials are only listed as an example, the 2D materials that may be included in the semiconductor memory device of the present disclosure are not limited by the above-mentioned materials.

Although the cell conductive line 140 is shown to be a single film, this is only for convenience of explanation, and the present disclosure is not limited thereto. That is, unlike the shown example, the cell conductive line 140 may include a plurality of conductive films in which conductive materials are stacked.

The cell line capping film 144 may be disposed on the cell conductive line 140. The cell line capping film 144 may extend in the second direction DR2 along the upper surface of the cell conductive line 140. The cell line capping film 144 may include, for example, at least one of a silicon nitride film, a silicon oxynitride, a silicon carbonitride, and a silicon oxycarbonitride. In some implementations, the cell line capping film 144 may include a silicon nitride film. The cell line capping film 144 is shown as being a single film, but the present disclosure is not limited thereto.

A bit line contact 146 may be disposed between the cell conductive line 140 and the substrate 100. That is, the cell conductive line 140 may be disposed on the bit line contact 146. For example, the bit line contact 146 may be disposed at a point on which the cell conductive line 140 intersects a central portion of the cell active region ACT having a long island shape. The bit line contact 146 may be disposed between the bit line connecting region 103a of the cell active region ACT and the cell conductive line 140. The bit line contact 146 may be connected to the bit line connecting region 103a.

The plurality of bit line contacts 146 may be disposed along the second direction DR2. Each cell conductive line 140 may be disposed on the plurality of bit line contacts 146 and extend along the second direction DR2.

The bit line contact 146 may electrically connect the cell conductive line 140 and the substrate 100. Here, the bit line contact 146 may correspond to a direct contact DC. The bit line contact 146 may include, for example, at least one of a semiconductor material doped with impurities, a conductive silicide compound, a conductive metal nitride, and a metal.

In FIG. 7, the thickness of the cell conductive line 140 in the region that overlaps the upper surface 146US of the bit line contact may be smaller than the thickness of the cell conductive line 140 in the region that does not overlap the upper surface 146US of the bit line contact. Unlike the shown example, the thickness of the cell conductive line 140 in the region that overlaps the upper surface 146US of the bit line contact may be the same as the thickness of the cell conductive line 140 in the region that does not overlap the upper surface 146US of the bit line contact.

A cell insulating film 130 may be disposed on the substrate 100 and the cell element isolation film 105. More specifically, the cell insulating film 130 may be disposed on the substrate 100 and the cell element isolation film 105 on which the bit line contact 146 is not formed. The cell insulating film 130 may be disposed between the substrate 100 and the cell conductive line 140, and between the cell element isolation film 105 and the cell conductive line 140. In some implementations, the upper surface 146US of the bit line contact may be higher than the upper surface 130US of the cell insulating film on the basis of the upper surface of the substrate 100.

In some implementations, the cell insulating film 130 may be a single film, and in some implementations the cell insulating film 130 may be a multi-film including a first cell insulating film 131 and a second cell insulating film 132. For example, the first cell insulating film 131 may include a silicon oxide film, and the second cell insulating film 132 may include a silicon nitride film, but the present disclosure is not limited thereto. In some implementations, the cell insulating film 130 may include three or more insulating films.

A cell line spacer 150 may be disposed on the side wall of the cell conductive line 140 and the side wall of the cell line capping film 144. In the portion of the cell conductive line 140 in which the bit line contact 146 is formed, the cell line spacer 150 may be formed on the substrate 100 and the cell element isolation film 105. The cell line spacer 150 may be disposed on the side wall of the cell conductive line 140, the side wall of the cell line capping film 144, and the side wall of the bit line contact 146.

In a remaining portion of the cell conductive line 140 in which the bit line contact 146 is not formed, the cell line spacer 150 may be disposed on the cell insulating film 130. The cell line spacer 150 may be disposed on the side wall of the cell conductive line 140 and the side wall of the cell line capping film 144.

Although the cell line spacer 150 is shown as being a single film, this is only for convenience of explanation, and the present disclosure is not limited thereto. In other words, the cell line spacer 150 may have a multi-film structure. The cell line spacer 150 may include, for example, but not limited to, a silicon oxide film, a silicon nitride film, a silicon oxynitride film (SiON), a silicon oxycarbonitride film (SiOCN), air, and a combination thereof.

A fence pattern 170 may be disposed on the substrate 100 and the cell element isolation film 105. The fence pattern 170 may be disposed to overlap the cell gate structure 110 formed inside the substrate 100 and the cell element isolation film 105. The fence pattern 170 may be disposed on the cell gate capping pattern 113.

The fence pattern 170 may be disposed between the bit line structures 140ST extending in the second direction DR2. The fence pattern 170 may include, for example, at least one of silicon oxide, silicon nitride, silicon oxynitride, and combinations thereof.

The plurality of storage contacts 120 may be disposed between the cell conductive lines 140 adjacent to each other in the first direction DR1. The storage contact 120 may be disposed between the fence patterns 170 adjacent to each other in the second direction DR2. The storage contact 120 may overlap the substrate 100 and the cell element isolation film 105 between the adjacent cell conductive lines 140 in the fourth direction DR4. The storage contact 120 may be connected to the storage connecting region 103b of the cell active region ACT. Here, the storage contact 120 may correspond to the buried contact BC.

The storage contact 120 may include, for example, at least one of an impurity-doped semiconductor material, a conductive silicide compound, a conductive metal nitride, and a metal.

A storage pad 160 may be disposed on each storage contact 120. The storage pad 160 may be electrically connected to the storage contact 120. The storage pad 160 may be connected to the storage connecting region 103b of the cell active region ACT. Here, the storage pad 160 may correspond to the landing pad LP.

The storage pad 160 may overlap a part of the upper surface of the cell conductive line 140. The storage pad 160 may include, for example, at least one of a semiconductor material doped with impurities, a conductive silicide compound, a conductive metal nitride, a conductive metal carbide, a metal, and a metal alloy.

A pad isolation insulating film 180 may be disposed on the storage pad 160 and the cell conductive line 140. For example, the pad isolation insulating film 180 may be disposed on the cell line capping film 144. The pad isolation insulating film 180 may define the storage pad 160 that forms a plurality of isolation regions. The pad isolation insulating film 180 may not cover the upper surface of the storage pad 160. The pad isolation insulating film 180 may fill a pad isolation recess. The pad isolation recess may separate the adjacent storage pads 160.

The pad isolation insulating film 180 may include an insulating material and electrically isolate the storage pads 160 from each other. For example, the pad isolation insulating film 180 may include at least one of, for example, but not limited to, a silicon oxide film, a silicon nitride film, a silicon oxynitride film, a silicon oxycarbonitride film, and a silicon carbonitride film.

A lower peri-interlayer insulating film 292 may be disposed on the substrate 100 of the peri-region 24. The lower peri-interlayer insulating film 292 may be disposed on the cell region isolation film 22.

The lower peri-interlayer insulating film 292 may include an oxide-based insulating material. For example, the lower peri-interlayer insulating film 292 may include silicon oxide.

An upper etch stop film 295 may be disposed on the upper surface of the storage pad 160 and the upper surface of the pad isolation insulating film 180. The upper etch stop film 295 may be disposed on the lower peri-interlayer insulating film 292. The upper etch stop film 295 may include, for example, at least one of silicon nitride (SiN), silicon carbonitride (SiCN), silicon oxycarbonitride (SiOCN), silicon oxycarbide (SiOC), and silicon boron nitride (SiBN).

The data storage pattern DSP may be disposed on the storage pad 160. The data storage pattern DSP is connected to the storage pad 160. A part of the data storage pattern DSP may be disposed in the upper etch stop film 295.

As an example, the data storage pattern DSP may be a capacitor. The data storage pattern DSP includes a lower electrode 191, a capacitor dielectric film 192, and an upper electrode 193. For example, the upper electrode 193 may be a plate upper electrode having a plate shape.

The lower electrode 191 may be disposed on the storage pad 160. The lower electrode 191 may have, for example, a pillar shape. The capacitor dielectric film 192 is disposed on the lower electrode 191. The capacitor dielectric film 192 may be formed along the profile of the lower electrode 191. The upper electrode 193 is disposed on the capacitor dielectric film 192. The upper electrode 193 may cover the outer side wall of the lower electrode 191. Although the upper electrode 193 is shown as being a single film, this is only for convenience of explanation, and the present disclosure is not limited thereto. In some implementations, the lower electrode 191 may have a cylindrical shape with one side open.

The lower electrode 191 and the upper electrode 193 may each include, for example, but not limited to, a doped semiconductor material, a conductive metal nitride (e.g., titanium nitride, tantalum nitride, niobium nitride or tungsten nitride), a metal (e.g., ruthenium, iridium, titanium or tantalum), and a conductive metal oxide (e.g., iridium oxide or niobium oxide).

The capacitor dielectric film 192 may include, for example, but not limited to, one of silicon oxide, silicon nitride, silicon oxynitride, a high dielectric constant material, and combinations thereof. In some implementations, the capacitor dielectric film 192 may include a stacked film structure in which zirconium oxide, aluminum oxide, and zirconium oxide are sequentially stacked. In some implementations, the capacitor dielectric film 192 may include a dielectric film containing hafnium (Hf). In some implementations, the capacitor dielectric film 192 may have a stacked film structure of a ferroelectric material film and a paraelectric material film.

The data storage patterns DSP may be a variable resistance pattern that may be switched between two resistance statuses by an electric pulse applied to the memory element. For example, the data storage patterns DSP may include a phase-change material, perovskite compounds, a transition metal oxide, magnetic materials, ferromagnetic materials or antiferromagnetic materials, in which a crystalline status changes depending on the amount of current.

An upper peri-interlayer insulating film 293 may be disposed on the upper etch stop film 295. The upper peri-interlayer insulating film 293 may cover a side wall of the upper electrode 193. The upper peri-interlayer insulating film 293 may include, for example, but not limited to, at least one of a silicon oxide film, a silicon nitride film, a silicon oxynitride film, a silicon oxycarbonitride film, and a silicon carbonitride film.

A peri-connecting line 265 may be disposed on the cell region isolation film 22. The peri-connecting line 265 may extend up to the peri-region 24. For example, the peri-connecting line 265 may be connected to the gate electrode and/or source/drain region of the peri-transistor disposed in the peri-region 24. The peri-connecting line 265 may connect the cell gate electrode 112 and the peri-transistor disposed in the peri-region 24.

A plurality of cell gate plugs 261 may be disposed on each cell gate electrode 112. Each cell gate plug 261 may be connected to the corresponding cell gate electrode 112. For example, the cell gate plug 261 is electrically connected to the cell gate electrode 112.

The cell gate plug 261 is disposed between the cell gate electrode 112 and the peri-connecting line 265. The cell gate plug 261 connects the cell gate electrode 112 and the peri-connecting line 265.

The cell gate plug 261 may be disposed on the contact region 112CR of the cell gate electrode. The cell gate plug 261 may be connected to the contact region 112CR of the cell gate electrode.

In a plan view, the cell gate plug 261 may be in contact with at least one of the long side walls 112LSW1 and 112LSW2 of the cell gate electrode 112. In the plan view, the cell gate plug 261 may be in contact with the long side walls 112LSW1 and 112LSW2 of the cell gate electrode 112 in which end portions are expanded and have a stepped shape. In some implementations, the cell gate plug 261 may not be in contact with the long side walls 112LSW1 and 112LSW2 of the cell gate electrode 112 having a straight line shape.

In the plan view, the cell gate plug 261 may be in contact with the short side wall 112SSW of the cell gate electrode 112. In some implementations, the cell gate plug 261 may not be in contact with the short side wall 112SSW of the cell gate electrode 112.

In FIGS. 9 and 10, the cell gate plug 261 may include first to fourth cell gate plugs 261_1, 261_2, 261_3, and 261_4. A first cell gate plug 261_1 may be connected to the contact region 112CR of the first cell gate electrode 112_1. A second cell gate plug 261_2 may be connected to the contact region 112CR of the second cell gate electrode 112_2. A third cell gate plug 261_3 may be connected to the contact region 112CR of the third cell gate electrode 112_3. A fourth cell gate plug 261_4 may be connected to the contact region 112CR of the fourth cell gate electrode 112_4.

The first cell gate plug 261_1 and the second cell gate plug 261_2 may be arranged in the second direction DR2. The third cell gate plug 261_3 and the fourth cell gate plug 261_4 may be arranged in the second direction DR2. A first plug group includes the first cell gate plug 261_1 and the second cell gate plug 261_2, and a second plug group includes the third cell gate plug 261_3 and the fourth cell gate plug 261_4. In some implementations, the first plug group and the second plug group may be disposed in zigzags across the cell region 20.

In the plan view, the first cell gate plug 261_1 may be in contact with the first sub-long side wall 112LSW11 of the first cell gate electrode 112_1. The first cell gate plug 261_1 may not be in contact with the second sub-long side wall 112LSW21 of the first cell gate electrode 112_1. The first cell gate plug 261_1 may be in contact with the first sub-short side wall 112SSW1 of the first cell gate electrode 112_1.

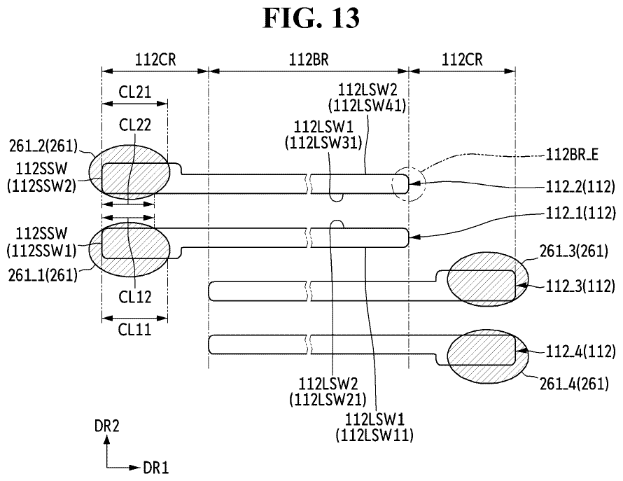

In the plan view, a length of the first cell gate plug 261_1 contacting the first sub-long side wall 112LSW11 of the first cell gate electrode 112_1 may be a first contact length CL11. A length of the first cell gate plug 261_1 contacting the second sub-long side wall 112LSW21 of the first cell gate electrode 112_1 may be a second contact length (CL12 of FIG. 13).

In some implementations, the second contact length by which the first cell gate plug 261_1 is in contact with the second sub-long side wall 112LSW21 of the first cell gate electrode 112_1 may be 0. For example, the first contact length CL11 may be greater than the second contact length.

In the plan view, the second cell gate plug 261_2 may not be in contact with the third sub-long side wall 112LSW31 of the second cell gate electrode 112_2. The second cell gate plug 261_2 may be in contact with the fourth sub-long side wall 112LSW41 of the second cell gate electrode 112_2. The second cell gate plug 261_2 may be in contact with the second sub-short side wall 112SSW2 of the second cell gate electrode 112_2.

In the plan view, a length of the second cell gate plug 261_2 contacting the third sub-long side wall 112LSW31 of the second cell gate electrode 112_2 may be a third contact length (CL22 of FIG. 13). A length of the second cell gate plug 261_2 contacting the fourth sub-long side wall 112LSW41 of the second cell gate electrode 112_2 may be a fourth contact length CL21.

In some implementations, the third contact length by which the second cell gate plug 261_2 is in contact with the third sub-long side wall 112LSW31 of the second cell gate electrode 112_2 may be 0. For example, the fourth contact length CL21 may be greater than the third contact length.

In the plan view, the first cell gate plug 261_1 may include a first plug width center line WCL_P1. The first plug width center line WCL_P1 may extend in the first direction DR1. The first plug width center line WCL_P1 may pass through the center of the width of the first cell gate plug 261_1 in the second direction DR2.

In FIG. 11, in the plan view, the first cell gate plug 261_1 may have a first plug width W_CP in the second direction DR2. The width of the first cell gate plug 261_1 in the second direction DR2 may change. The first plug width W_CP may be the largest value among the varying widths of the first cell gate plug 261_1. The first cell gate plug 261_1 may include a plug width center point 261P1. The first plug width center line WCL_P1 may pass through the plug width center point 261P1 and extend in the first direction DR1. In the plan view, the plug width center point 261P1 may not be a geometric center of the first cell gate plug 261_1. The plug width center point 261P1 may be a point which is half the first plug width W_CP.

In the plan view, the second cell gate plug 261_2 may include a second plug width center line WCL_P2. The second plug width center line WCL_P2 may extend in the first direction DR1.

The first plug width center line WCL_P1 may be spaced apart from the first body width center line WCL_W11 in the second direction DR2. The first plug width center line WCL_P1 may be parallel to the first body width center line WCL_W11. The first plug width center line WCL_P1 may not meet the first body width center line WCL_W11.

The first plug width center line WCL_P1 may be parallel to the first contact width center line WCL_W12. The first plug width center line WCL_P1 may not meet the first contact width center line WCL_W12. In some implementations, the first plug width center line WCL_P1 may be disposed on the same line as the first contact width center line WCL_W12.

The second plug width center line WCL_P2 may be spaced apart from the second body width center line WCL_W21 in the second direction DR2. The second plug width center line WCL_P2 may be parallel to the second body width center line WCL_W21. The second plug width center line WCL_P2 may not meet the second body width center line WCL_W21.

The second plug width center line WCL_P2 may be parallel to the second contact width center line WCL_W22. In some implementations, the second plug width center line WCL_P2 may be placed on the same line as the second contact width center line WCL_W22.

The first plug width center line WCL_P1 may be parallel to the second plug width center line WCL_P2. The first plug width center line WCL_P1 and the second plug width center line WCL_P2 may be spaced apart by a third spaced distance L13 in the second direction DR2. For example, the third spaced distance L13 is greater than the first spaced distance L11.

Although the third spaced distance L13 is shown as being greater than the second spaced distance L12, the present disclosure is not limited thereto. In some implementations, the third spaced distance L13 may be the same as the second spaced distance L12. In some implementations, the third spaced distance L13 may be smaller than the second spaced distance L12.

The first plug width center line WCL_P1 and the first sub-long side wall 112LSW11 may be spaced apart by a fourth spaced distance L22 in the second direction DR2. For example, the fourth spaced distance L22 may be a spaced distance between the first sub-long side wall 112LSW11 included in the body region 112BR of the first cell gate electrode 112_1 and the first plug width center line WCL_P1. The first plug width center line WCL_P1 and the second sub-long side wall 112LSW21 may be spaced apart by a fifth spaced distance L21 in the second direction DR2. For example, the fourth spaced distance L22 is smaller than the fifth spaced distance L21.

In the plan view, the first cell gate plug 261_1 may be disposed to be biased to one side on the basis of the first body width center line WCL_W11. Also, the second cell gate plug 261_2 may be disposed to be biased to one side on the basis of the second body width center line WCL_W21.

Because the first cell gate plug 261_1 is biased to one side and is in contact with the first cell gate electrode 112_1, the contact area between the first cell gate plug 261_1 and the first cell gate electrode 112_1 may be increased. That is, the resistance between the first cell gate plug 261_1 and the first cell gate electrode 112_1 may decrease. Also, the first cell gate plug 261_1 may be stably electrically connected to the first cell gate electrode 112_1.

Even if the interval between the closest first cell gate electrode 112_1 and the second cell gate electrode 112_2 decreases, the first cell gate electrode 112_1 and the second cell gate electrode 112_2 may be stably connected to the first cell gate plugs 261_1 and the second cell gate plug 261_2. Accordingly, the performance and reliability of the semiconductor memory device can be improved.

In some implementations, the first cell gate plug 261_1 and the second cell gate plug 261_2 may be applied to the third cell gate plug 261_3 and the fourth cell gate plug 261_4.

The peri-connecting line 265 and the cell gate plug 261 may each include at least one of an impurity-doped semiconductor material, a conductive silicide compound, a conductive metal nitride, a conductive metal carbide, a metal, and a metal alloy. Although the peri-connecting line 265 and the cell gate plug 261 are shown as being different films from each other, this is only for convenience of explanation, and the present disclosure is not limited thereto.

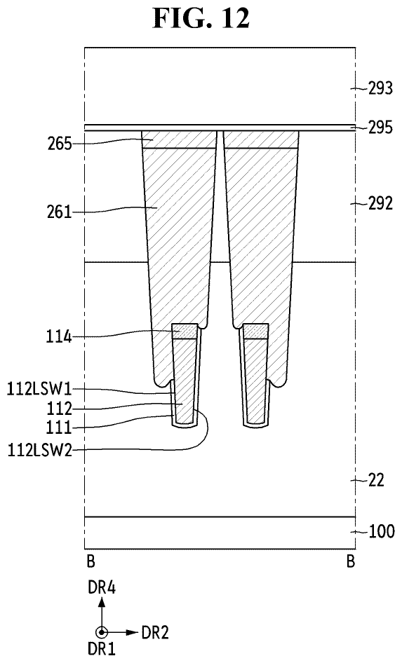

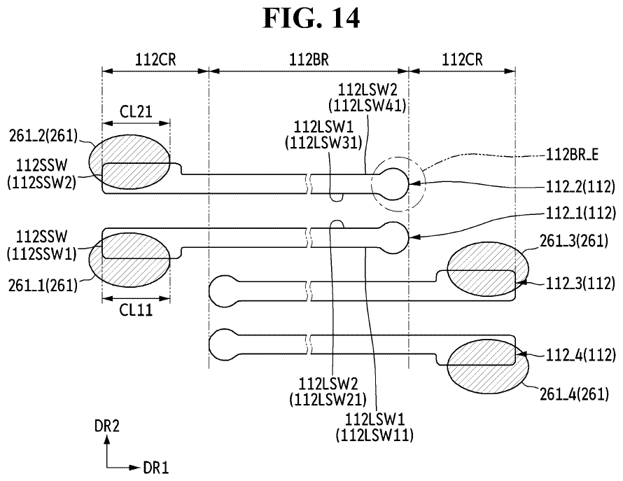

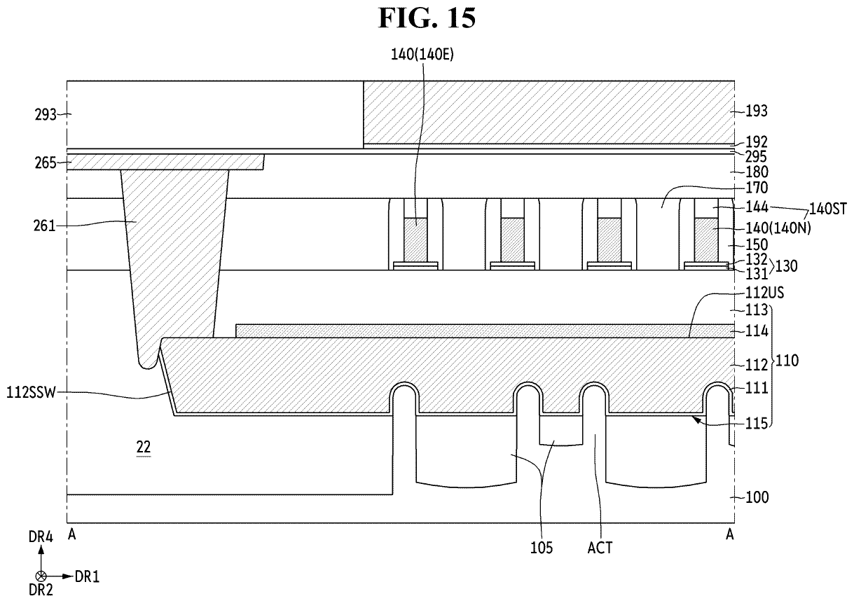

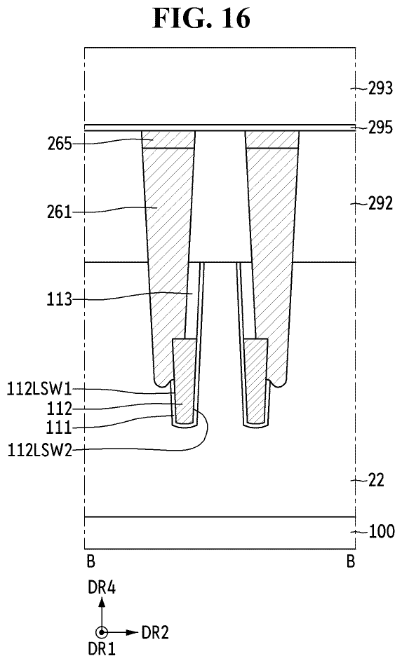

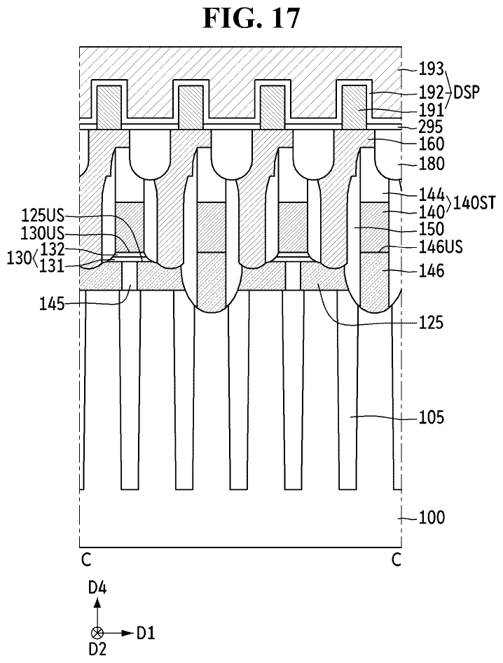

FIGS. 12 and 13 are diagrams a showing an example of a semiconductor memory device according to some implementations. FIG. 14 is a diagram showing an example of a semiconductor memory device according to some implementations. FIGS. 15 and 16 are diagrams showing an example of a semiconductor memory device according to some implementations. FIG. 17 is a diagram showing an example of a semiconductor memory device according to some implementations. For convenience of explanation, differences from those explained using FIGS. 1 to 11 will be mainly explained.

For reference, FIGS. 13 and 14 are diagrams showing examples of the cell gate electrode and the cell gate plug included in the cell gate structure of FIG. 3, respectively, according to some implementations.

In FIGS. 12 and 13, a semiconductor memory device may include the cell gate plug 261 that come into contact with the first long side wall 112LSW1 of the cell gate electrode and the second long side wall 112LSW2 of the cell gate electrode.

In a plan view, the cell gate plug 261 may be in contact with the long side walls 112LSW1 and 112LSW2 of the cell gate electrode 112 included in the contact region 112CR of the cell gate electrode 112.

The first cell gate plug 261_1 may be in contact with the second sub-long side wall 112LSW21 of the first cell gate electrode 112_1. In the plan view, the second contact length CL12 by which the first cell gate plug 261_1 is in contact with the second sub-long side wall 112LSW21 of the first cell gate electrode is not 0.

The second cell gate plug 261_2 may be in contact with the third sub-long side wall 112LSW31 of the second cell gate electrode 112_2. In the plan view, the third contact length CL22 by which the second cell gate plug 261_2 is in contact with the third sub-long side wall 112LSW31 of the second cell gate electrode 112_2 is not 0.

In some implementations, the first cell gate plug 261_1 may not be in contact with the second sub-long side wall 112LSW21 of the first cell gate electrode 112_1. In some implementations, the second cell gate plug 261_2 may not be in contact with the third sub-long side wall 112LSW31 of the second cell gate electrode 112_2.

In FIG. 14, the width of the cell gate electrode 112 at the trailing end 112BR_E of the cell gate electrode 112 in the second direction DR2 may increase and then decrease. For example, the width of the cell gate electrode 112 at the trailing end 112BR_E of the cell gate electrode 112 may increase and then decrease, as goes away from the cell gate electrode contact region 112CR.

In FIGS. 15 and 16, the cell gate capping conductive film 114 may cover a part of the upper surface 112US of the cell gate electrode.

The cell gate electrode 112 may include a first portion covered by the cell gate capping conductive film 114, and a second portion not covered by the cell gate capping conductive film 114. The cell gate plug 261 may be disposed on the second portion of the cell gate electrode 112. At least a part of the cell gate plug 261 may overlap the second portion of the cell gate electrode 112 in the fourth direction DR4.

In FIG. 17, the storage contact 125 may be disposed on the substrate 100 and the cell element isolation film 105. The storage contact 125 may be disposed on an upper surface of the cell element isolation film 105. A lower face of the storage contact 125 may be disposed on the upper surface of the cell element isolation film 105. The storage contact 125 may be in contact with the upper surface of the cell element isolation film 105.

On the basis of the upper surface of the cell element isolation film 105, the upper surface 125US of the storage contact may be lower than the upper surface 146US of the bit line contact. On the basis of the upper surface of the cell element isolation film 105, the upper surface 125US of the storage contact may be lower than the lower face of the cell conductive line 140.

A contact isolation pattern 145 may space the adjacent storage contacts 125 in the first direction DR1. When the storage contact 125 includes a first storage contact and a second storage contact spaced apart in the first direction DR1, the contact isolation pattern 145 may separate the first storage contact and the second storage contact in the first direction DR1. In some implementations, the contact isolation pattern 145 may also separate the adjacent storage contacts 125 in the second direction DR2.

The cell line spacer 150 may be disposed on the upper surface 125US of the storage contact. The cell insulating film 130 may cover the upper surface 125US of the storage contact. When the storage contact 125 includes a first storage contact and a second storage contact spaced apart in the first direction DR1, the cell insulating film 130 may cover the upper surface of the first storage contact and the upper surface of the second storage contact.

The upper surface 130US of the cell insulating film may be disposed in the same plane as the upper surface 146US of the bit line contact. That is, a height of the upper surface 130US of the cell insulating film may be the same as a height of the upper surface 146US of the bit line contact on the basis of the upper surface of the cell element isolation film 105. The cell conductive line 140 may be disposed on the upper surface 130US of the cell insulating film.

The contact isolation pattern 145 may include, for example, at least one of silicon nitride (SiN), silicon oxynitride (SiON), silicon oxide (SiO₂), silicon carbonitride (SiCN), silicon oxycarbonitride (SiOCN), and combinations thereof. Although a width of the cell insulating film 130 in the first direction DR1 is shown to decrease as it goes away from the substrate 100, the present disclosure is not limited thereto.

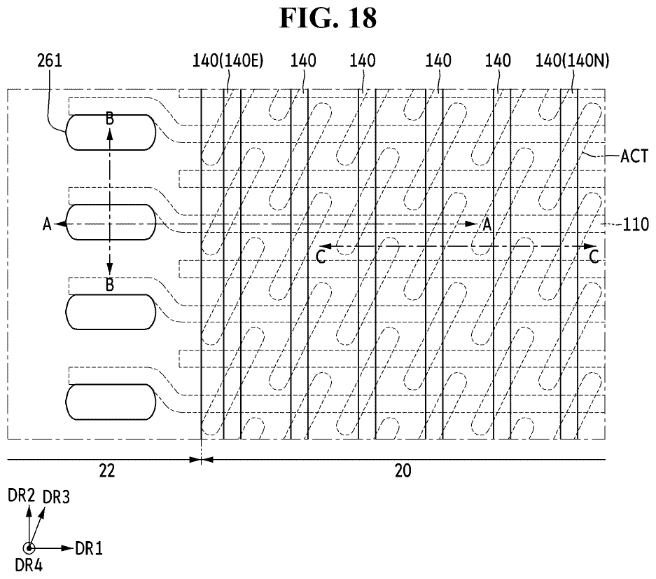

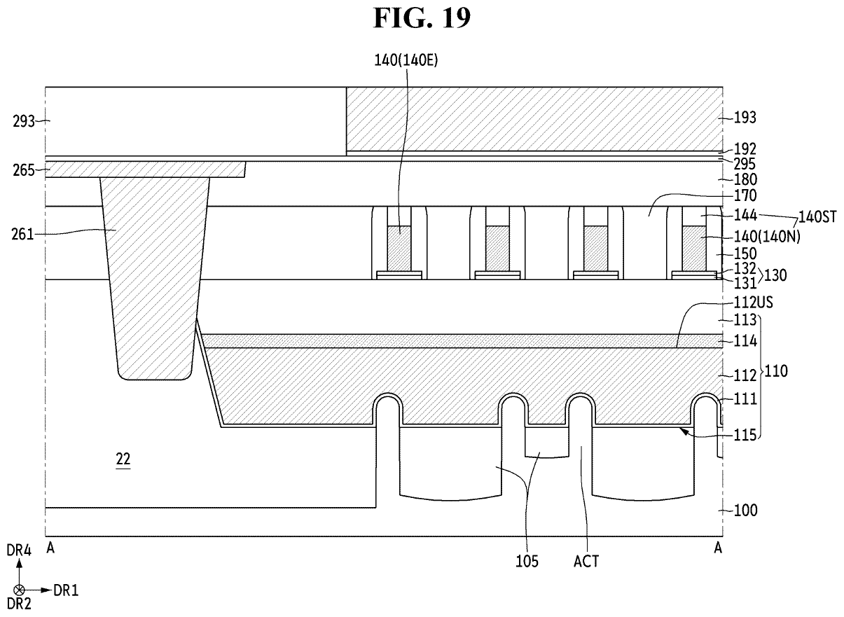

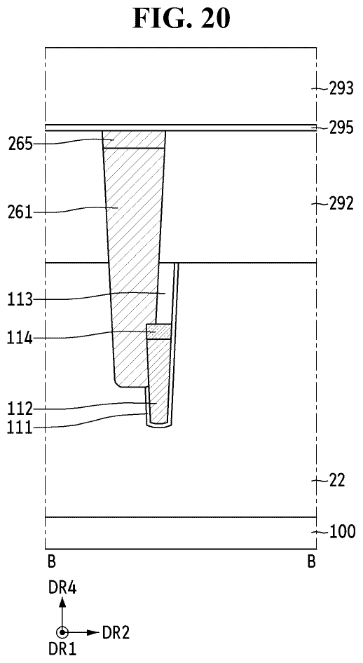

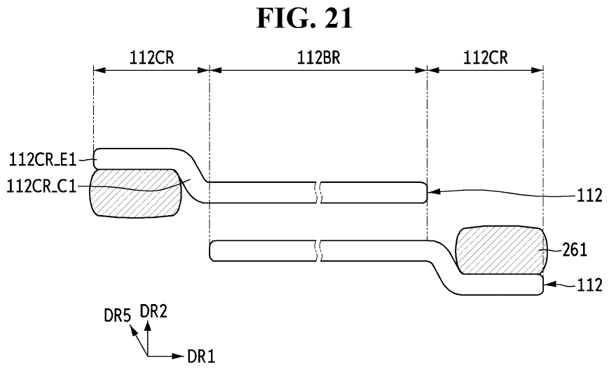

FIG. 18 is a diagram showing an example of a semiconductor memory device according to some implementations. FIGS. 19 and 20 are cross-sectional views taken along lines A-A and B-B of FIG. 18 according to some implementations. FIG. 21 is a diagram showing an example of a placement relationship between the cell gate electrode and the cell gate plug included in the cell gate structure of FIG. 18 according to some implementations. For convenience of explanation, differences from those explained using FIGS. 1 to 11 will be mainly explained.

For reference, FIG. 18 is a plan view that schematically shows an example of a region R2 of FIG. 1 according to some implementations.

In FIGS. 18 to 23, the contact region 112CR of the cell gate electrode 112 may include a first extending portion 112CR_E1 connected in the first direction DR1, and a first connecting portion 112CR_C1 extending in a fifth direction DR5.

The first extending portion 112CR_E1 may be spaced apart from the body region 112BR of the cell gate electrode 112 in the first direction DR1. The first extending portion 112CR_E1 does not overlap the body region 112BR of the cell gate electrode 112 in the second direction DR2. When the first extending portion 112CR_E1 extends in the first direction DR1, the extended portion of the first extending portion 112CR_E1 may be aligned with the body region 112BR of the cell gate electrode 112.

The first connecting portion 112CR_C1 may be disposed between the first extending portion 112CR_E1 and the body region 112BR of the cell gate electrode 112. The first connecting portion 112CR_C1 may connect the first extending portion 112CR_E1 and the body region 112BR of the cell gate electrode 112. Here, the fifth direction DR5 may be perpendicular to the fourth direction DR4. The fifth direction DR5 may form any angle with the first direction DR1, the second direction DR2, and the third direction DR3. In some implementations, the fifth direction DR5 may be the same direction as the second direction DR2.

The cell gate plug 261 may come into contact with the long side wall of the cell gate electrode 112 extending in the first direction DR1. In a plan view, the contact region 112CR of the cell gate electrode 112 may cover a part of an outer circumferential surface of the cell gate plug 261.

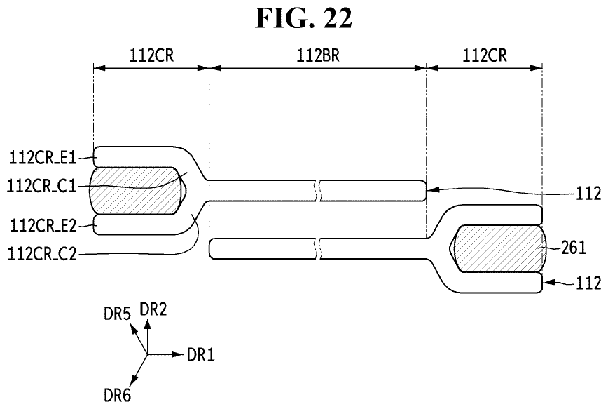

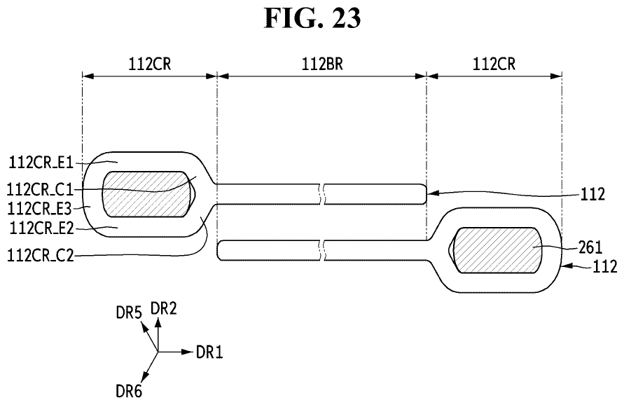

FIGS. 22 and 23 are diagrams showing an example of a semiconductor memory device according to some implementations. For convenience of explanation, differences from those explained using FIGS. 18 to 21 will be mainly explained.

For reference, FIGS. 22 and 23 are diagrams showing an example of a placement relationship between the cell gate electrode and the cell gate plug included in the cell gate structure of FIG. 18 according to some implementations.

In FIGS. 22 and 23, the contact region 112CR of the cell gate electrode may further include a second extending portion 112CR_E2 connected in the first direction DR1, and a second connecting portion 112CR_C2 extending in a sixth direction DR6.

The second extending portion 112CR_E2 may be spaced apart from the body region 112BR of the cell gate electrode 112 in the first direction DR1. The second extending portion 112CR_E2 does not overlap the body region 112BR of the cell gate electrode 112 in the second direction DR2. The second extending portion 112CR_E2 may be spaced apart from the first extending portion 112CR_E1 in the second direction DR2.

The second connecting portion 112CR_C2 may be disposed between the second extending portion 112CR_E2 and the body region 112BR of the cell gate electrode 112. The second connecting portion 112CR_C2 may connect the second extending portion 112CR_E2 and the body region 112BR of the cell gate electrode 112. The first connecting portion 112CR_C1 and the second connecting portion 112CR_C2 may diverge from the body region 112BR of the cell gate electrode 112.

Here, the sixth direction DR6 may be perpendicular to the fourth direction DR4. The sixth direction DR6 may form any angle with the first direction DR1, the second direction DR2, and the fifth direction DR5. As an example, the sixth direction DR6 may form any angle with the third direction DR3. As another example, the sixth direction DR6 may be the same direction as the third direction DR3. As yet another example, the sixth direction DR6 may be the same direction as the second direction DR2.

Unlike that shown in FIG. 22, the contact region 112CR of the cell gate electrode 12 may not include at least one of the first extending portion 112CR_E1 and the second extending portion 112CR_E2.

In FIG. 23, the contact region 112CR of the cell gate electrode 112 may further include a third extending portion 112CR_E3 extending in the second direction DR2. The third extending portion 112CR_E3 may connect the first extending portion 112CR_E1 and the second extending portion 112CR_E2. In a plan view, the contact region 112CR of the cell gate electrode 112 may entirely cover the outer circumferential surface of the cell gate plug 261.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor memory device comprising:
a substrate including a cell region and a peri-region defined around the cell region;
a cell region isolation film disposed in the substrate and isolating the cell region and the peri-region;
a first cell gate structure disposed in the cell region and the cell region isolation film, the first cell gate structure including a first cell gate electrode extending in a first direction; and
a first cell gate plug disposed on the first cell gate electrode and connected to the first cell gate electrode,
wherein the first cell gate electrode includes a first long side wall and a second long side wall that extend in the first direction and oppose to each other in a second direction,
wherein, in a plan view, the first cell gate plug contacts the first long side wall of the first cell gate electrode along a first contact length,
wherein, in the plan view, the first cell gate plug contacts the second long side wall of the first cell gate electrode along a second contact length, and
wherein the first contact length is greater than the second contact length.

2. The semiconductor memory device of claim 1,
wherein the first cell gate electrode includes a short side wall that connects the first long side wall of the first cell gate electrode with the second long side wall of the first cell gate electrode, and
wherein the first cell gate plug contacts the short side wall of the first cell gate electrode.

3. The semiconductor memory device of claim 1, wherein the first cell gate plug is spaced apart from the second long side wall of the first cell gate electrode.

4. The semiconductor memory device of claim 1, further comprising:
a second cell gate electrode disposed in the cell region and the cell region isolation film, the second cell gate electrode including a second cell gate electrode spaced apart from the first cell gate electrode in the second direction; and
a second cell gate plug disposed on the second cell gate electrode, the second cell gate plug being connected to the second cell gate electrode,
wherein the first cell gate plug and the second cell gate plug are arranged in the second direction, and
wherein no additional cell gate electrode is disposed between the first cell gate electrode and the second cell gate electrode.

5. The semiconductor memory device of claim 4,
wherein the second cell gate electrode includes a third long side wall and a fourth long side wall that extend in the first direction and oppose to each other in the second direction,
wherein the third long side wall of the second cell gate electrode faces the second long side wall of the first cell gate electrode,
wherein, in a plan view, the second cell gate plug contacts the third long side wall of the second cell gate electrode along a third contact length,
wherein, in the plan view, the second cell gate plug contacts the fourth long side wall of the second cell gate electrode along a fourth contact length, and
wherein the fourth contact length is greater than the third contact length.

6. The semiconductor memory device of claim 1, further comprising:
a second cell gate structure disposed in the cell region and the cell region isolation film, the second cell gate structure including a second cell gate electrode spaced apart from the first cell gate electrode in the second direction,
wherein the first cell gate electrode and the second cell gate electrode each includes a body region and a contact region,
wherein the body region of the first cell gate electrode and the body region of the second cell gate electrode overlap with each other in the second direction,
wherein the contact region of the first cell gate electrode does not overlap the second cell gate electrode in the second direction,
wherein the contact region of the second cell gate electrode does not overlap the first cell gate electrode in the second direction,
wherein the first cell gate plug is in contact with the contact region of the first cell gate electrode, and
wherein no additional cell gate electrode is disposed between the first cell gate electrode and the second cell gate electrode.

7. The semiconductor memory device of claim 6, wherein the first long side wall of the first cell gate electrode faces the second cell gate electrode.

8. The semiconductor memory device of claim 6,
wherein the body region of the second cell gate electrode includes a trailing end, and
wherein a width of the second cell gate electrode increases in the second direction and then decreases at the trailing end of the second cell gate electrode in the second direction.

9. The semiconductor memory device of claim 6,
wherein the body region of the first cell gate electrode includes a first width center line extending in the first direction,
wherein the contact region of the first cell gate electrode includes a second width center line extending in the first direction, and
wherein the second width center line is spaced apart from the first width center line in the second direction.

10. The semiconductor memory device of claim 1,
wherein the first cell gate structure further includes a cell gate capping conductive film extending along an upper surface of the first cell gate electrode, the cell gate capping conductive film including a semiconductor material, and
wherein the cell gate capping conductive film covers an entire upper surface of the first cell gate electrode.

11. A semiconductor memory device comprising:
a substrate including a cell region and a peri-region defined around the cell region;
a cell region isolation film disposed in the substrate isolating the cell region and the peri-region;
a first cell gate structure disposed in the cell region and the cell region isolation film, the first cell gate structure including a first cell gate electrode extending in a first direction; and
a first cell gate plug disposed on the first cell gate electrode, the first cell gate plug being connected to the first cell gate electrode,
wherein the first cell gate electrode includes a body region and a contact region,
wherein the contact region of the first cell gate electrode is connected to the first cell gate plug, the contact region being disposed in the cell region isolation film,
wherein the first cell gate electrode includes a first long side wall and a second long side wall that extend in the first direction and oppose to each other in a second direction,
wherein the body region of the first cell gate electrode includes a first width center line extending in the first direction,
wherein the first cell gate plug includes a first plug width center line extending in the first direction, and
wherein the first width center line is spaced apart from the first plug width center line in the second direction.

12. The semiconductor memory device of claim 11,
wherein, in a plan view, the first cell gate plug contacts the first long side wall of the first cell gate electrode along a first contact length,
wherein, in the plan view, the first cell gate plug contacts the second long side wall of the first cell gate electrode along a second contact length, and
wherein the first contact length is greater than the second contact length.

13. The semiconductor memory device of claim 12,
wherein the first plug width center line is spaced apart from the first long side wall of the first cell gate electrode by a first spaced distance in the second direction,
wherein the first plug width center line is spaced apart from the second long side wall of the first cell gate electrode by a second spaced distance in the second direction, and
wherein the second spaced distance is greater than the first spaced distance.

14. The semiconductor memory device of claim 11,
wherein the contact region of the first cell gate electrode includes a second width center line extending in the first direction, and
wherein the second width center line is spaced apart from the first width center line in the second direction.

15. The semiconductor memory device of claim 11, further comprising:
a second cell gate electrode disposed in the cell region and the cell region isolation film, the second cell gate electrode including a second cell gate electrode spaced apart from the first cell gate electrode in the second direction; and
a second cell gate plug disposed on the second cell gate electrode and connected to the second cell gate electrode,
wherein the first cell gate plug and the second cell gate plug are arranged in the second direction,
wherein the second cell gate electrode includes a body region and a contact region,
wherein the contact region of the second cell gate electrode is connected to the second cell gate plug and is disposed inside the cell region isolation film,
wherein the body region of the second cell gate electrode includes a second width center line extending in the first direction,
wherein the second cell gate plug includes a second plug width center line extending in the first direction,
wherein the second width center line is spaced apart from the second plug width center line in the second direction, and
wherein no additional cell gate electrode is disposed between the first cell gate electrode and the second cell gate electrode.

16. The semiconductor memory device of claim 15, wherein a distance by which the first width center line and the second width center line are spaced apart in the second direction is smaller than a distance by which the first plug width center line and the second plug width center line are spaced apart in the second direction.

17. A semiconductor memory device comprising:
a substrate including a cell region and a peri-region defined around the cell region;
a cell region isolation film disposed in the substrate and isolating the cell region and the peri-region;
a cell gate structure disposed in the cell region and the cell region isolation film, the cell gate structure including a cell gate electrode extending in a first direction; and
a cell gate plug disposed on the cell gate electrode and connected to the cell gate electrode,
wherein the cell gate electrode includes a body region and a contact region,
wherein the contact region of the cell gate electrode is connected to the cell gate plug and disposed in the cell region isolation film,
wherein the contact region of the cell gate electrode includes a first connecting portion extending in a second direction different from the first direction, and a first extending portion extending in the first direction,
wherein the first connecting portion connects the first extending portion to the body region of the cell gate electrode, and
wherein the first extending portion does not overlap the body region of the cell gate electrode in a third direction perpendicular to the first direction.

18. The semiconductor memory device of claim 17,
wherein the contact region of the cell gate electrode further includes a second connecting portion, and a second extending portion extending in the first direction,
wherein the second extending portion is spaced apart from the first extending portion in the third direction, and
wherein the second connecting portion connects the second extending portion and the body region of the cell gate electrode.

19. The semiconductor memory device of claim 18,
wherein the contact region of the cell gate electrode further includes a third extending portion extending in the third direction, and
wherein the third extending portion connects the first extending portion and the second extending portion.

20. The semiconductor memory device of claim 17, wherein, in a plan view, the contact region of the cell gate electrode covers at least a part of an outer circumferential surface of the cell gate plug.
